(19) United States
(12) Patent Application Publication
(10) Pub. No.: US 2008/0092819 A1
(43) Pub. Date: Apr. 24, 2008

(54) SUBSTRATE SUPPORT STRUCTURE WITH RAPID TEMPERATURE CHANGE

(75) Inventors: David Bour, Cupertino, CA (US); Lori D. Washington, Union City, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/552,474

(22) Filed: Oct. 24, 2006

(51) Int. Cl. C23C 16/00

(52) U.S. Cl. 118/725; 427/248.1; 427/255.394

(57) ABSTRACT

The present invention relates to semiconductor reaction chambers including a substrate support structure with rapid temperature change capabilities. The methods and components of the present invention may be used substrate deposition and related processes where varied temperatures are used. In accordance with the advantages of the present invention, the reaction chambers and substrate support structures of the invention can change temperature within a short duration of time, thereby allowing quicker processing times. The substrate support structures generally include a susceptor surface formed from a material having configured so as to allow for rapid temperature change of greater than about 10° C./sec.

### BACKGROUND OF THE INVENTION

The present invention relates generally to the field of substrate processing equipment. More particularly, the present invention relates to a substrate support structure for use with semiconductor substrate processing equipment.

Group III-V semiconductors are increasingly being used in light-emitting diodes (LEDs) and laser diodes (LDs). Specific III-V semiconductors, such as gallium nitride (GaN), are emerging as important materials for the production of shorter wavelength LEDs and LDs, including blue and ultra-violet emitting optical and optoelectronic devices. Thus, there is increasing interest in the development of fabrication processes to make low-cost, high-quality III-V semiconductor films.

Metal-organic chemical vapor deposition (MOCVD) may be used to form III-V nitride films. MOCVD uses a reasonably volatile metal-organic Group III precursor such as trimethylgallium (TMGa) or trimethylaluminum (TMAl) to deliver the Group III metal to the substrate where it reacts with the nitrogen precursor (e.g., ammonium) to form the III-V nitride film. Two or more different Group III metallorganic precursors (e.g., Ga, Al, In, etc.) may be combined to make alloy films of GaN (e.g., AlGaN, InGaN, etc.), and dopants may also be more easily combined with the precursors to deposit an in-situ doped film layer.

The various steps of III-V nitride film deposition require the performance of processing steps at varied temperatures, depending on the nature of the device being manufactured. However, traditional designs have shortcomings that result in limitations in terms of, e.g., turn-around times between temperature changes, impurities, growth stops at interfaces, etc.

### BRIEF SUMMARY OF THE INVENTION

In part to address such shortcomings, in a first aspect the present invention provides a substrate support structure with rapid temperature change capabilities for use in a semiconductor processing unit for use in deposition of III-V nitride films.

The substrate support structure generally includes a susceptor surface configured so as to allow for rapid temperature change of greater than about 10° C./sec. In accordance with certain embodiments, the susceptor is configured so as allow for rapid temperature change of greater than about 20° C./sec, or in other embodiments, of greater than about 25° C./sec. Further, in certain embodiments, the susceptor is comprised of an about 1 mm to about 5 mm thick platform.

In certain aspects, the susceptor comprises heater elements to aid in uniform temperature distribution during heating.

In another aspect of the invention, a semiconductor processing unit for use in deposition of III-V nitride films is provided. The semiconductor processing unit generally includes: an enclosure; a substrate support structure configured to support at least one substrate wafer located within the enclosure; at least one heater configured to heat the substrate support structure and the at least one substrate wafer during processing; and a gas delivery system configured to deliver process gases to the enclosure during processing. The substrate support structure includes a susceptor surface configured so as to allow for rapid temperature change of greater than about 10° C./sec.

In yet another aspect of the invention, an LED cluster tool including semiconductor processing unit of the invention for use in deposition of III-V nitride films is provided.

In yet another aspect of the invention, a method for performing multiple semiconductor III-V nitride film processes in a single semiconductor processing unit is provided, wherein at least one of the processes is performed at a temperature which differs from the other processes. This method generally includes: providing a semiconductor processing unit of the invention for use in deposition of III-V nitride films; locating a first semiconductor wafer within a semiconductor chamber on a substrate support structure; performing a first process in the enclosure at a first temperature at a first temperature; modifying the set-point temperature of the semiconductor processing unit to a second temperature and allowing the semiconductor substrate support to reach the second temperature at a temperature rate of change of greater than about 10° C./sec; and performing at least a second process in the enclosure at the second temperature.

In certain aspects, the temperature change of greater than about 10° C./sec between process steps results in a III-V nitride film with lower film impurities at growth stop interfaces, as compared to III-V nitride films deposited utilizing temperature ramping of less than 10° C./sec between process steps.

These and other aspects of the invention will be described in more detail throughout the present specification and more particularly below in conjunction with the following drawings.

### BRIEF DESCRIPTION OF THE DRAWINGS

FIG. 1 provides a schematic illustration of a GaN-based LED;

FIG. 2 is a simplified representation of an exemplary CVD apparatus that may be used in implementing certain embodiments of the invention;

FIG. 3 provides a schematic illustration of a multichamber cluster tool used in embodiments of the invention;

FIG. 4 is flow diagram of an exemplary method for performing multiple MOCVD processes in a single chamber according to an embodiment of the present invention.

FIG. 5 is an illustrate plot comparing rapid temperature ramping in accordance with embodiments of the invention with conventional temperature ramping.

### DETAILED DESCRIPTION OF THE INVENTION

According to the present invention, techniques related to the field of substrate processing equipment, and methods of use, are provided. More particularly, the present invention relates to substrate support structures for use in substrate processing equipment with rapid temperature change capabilities. Merely by way of example, the methods and components of the present invention may be used in growth of III-V nitride films where varied temperatures are used. In accordance with the advantages of the present invention, the substrate processing equipment and substrate support structures of the invention can reach temperature within a short duration of time, thereby allowing quicker processing times.

In certain aspects of the invention, nitride films may be deposited epitaxially by, e.g., MOVPE or MOCVD (Metal-Organic Vapor Phase Epitaxy or Metal-Organic Chemical Vapor Deposition), on sapphire, SiC, or Si substrates, for visible LEDs, near-UV laser diodes, and high power transistors. MOCVD growth of III-V nitride films like GaN-based LEDs typically incorporates several temperature change steps, for example when adjusting between growth of the amorphous buffer layer and the thick crystalline GaN, and also between the InGaN multiple quantum well active region and the surrounding materials. The rate of temperature change within the reaction chamber is generally limited by the wafer carriers and susceptor structure, which are often thermally massive.

Without intending to be limited by theory, the substrate support structures of the invention with rapid temperature changes provide for shorter deposition run times with heat-up and cool-down times reduced. Improved efficiencies also translates into slightly lower ammonia and alkyl consumption during deposition processing.

Further, improvements in the structural quality of, e.g., GaN-on-sapphire epitaxial films may be obtained as a result of rapid temperature ramping between deposition steps. For instance, less GaN may evaporate as the temperature ramps up for deposition of n-GaN. In addition, shorter growth stops at interfaces where temperature changes occur may also improve material quality, e.g., by minimizing the accumulation of impurities at these interfaces. In addition, temperature ramping may be used as a parameter to control properties of films. For example the InGaN quantum well/barrier compositions may be controlled by temperature modulation rather than flow changes, or control of the solid-phase epitaxial conversion of the amorphous buffer layer into crystallites may be enhanced.

### 1. EXEMPLARY III-V NITRIDE FILM STRUCTURES

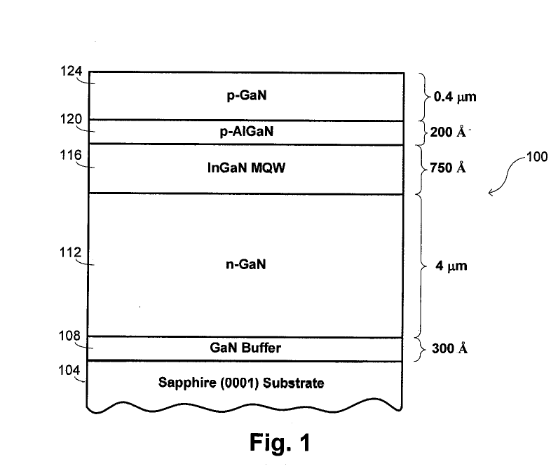

One typical III-V nitride-based film structure is illustrated in FIG. 1 as a GaN-based LED structure 100. It is fabricated over a sapphire (0001) substrate 104. An n-type GaN layer 112 is deposited over a GaN buffer layer 108 formed over the substrate. An active region of the device is embodied in a multi-quantum-well layer 1116, shown in the drawing to comprise an InGaN layer. A pn junction is formed with an overlying p-type AlGaN layer 120, with a p-type GaN layer 124 acting as a contact layer.

A typical fabrication process for such an LED may use a metalorganic chemical-vapor-deposition (“MOCVD”) process that follows cleaning of the substrate 104 in a processing chamber. The MOCVD deposition is accomplished by providing flows of suitable precursors to the processing chamber and using thermal processes to achieve deposition. For example, a GaN layer may be deposited using Ga and N precursors, perhaps with a flow of a fluent gas like N₂, II₂, and/or NH₃; an InGaN layer may be deposited using Ga, N, and In precursors, perhaps with a flow of a fluent gas; and an AlGaN layer may be deposited using Ga, N, and Al precursors, also perhaps with a flow of a fluent gas. In the illustrated structure 100, the GaN buffer layer 108 has a thickness of about 300 Å, and may have been deposited at a temperature of about 550° C. Subsequent deposition of the n-GaN layer 112 is typically performed at a higher temperature, such as around 1050° C. in one embodiment. The n-GaN layer 112 is relatively thick, with deposition of a thickness on the order of 4 μm requiring about 140 minutes. The InGaN multi-quantum-well layer 116 may have a thickness of about 750 Å, which may be deposited over a period of about 40 minutes at a temperature of about 750° C. The p-AlGaN layer 120 may have a thickness of about 200 Å, which may be deposited in about five minutes at a temperature of 950° C. The thickness of the contact layer 124 that completes the structure may be about 0.4 μm in one embodiment, and may be deposited at a temperature of about 1050° C. for around 25 minutes.

### 2. EXEMPLARY SUBSTRATE PROCESSING SYSTEM

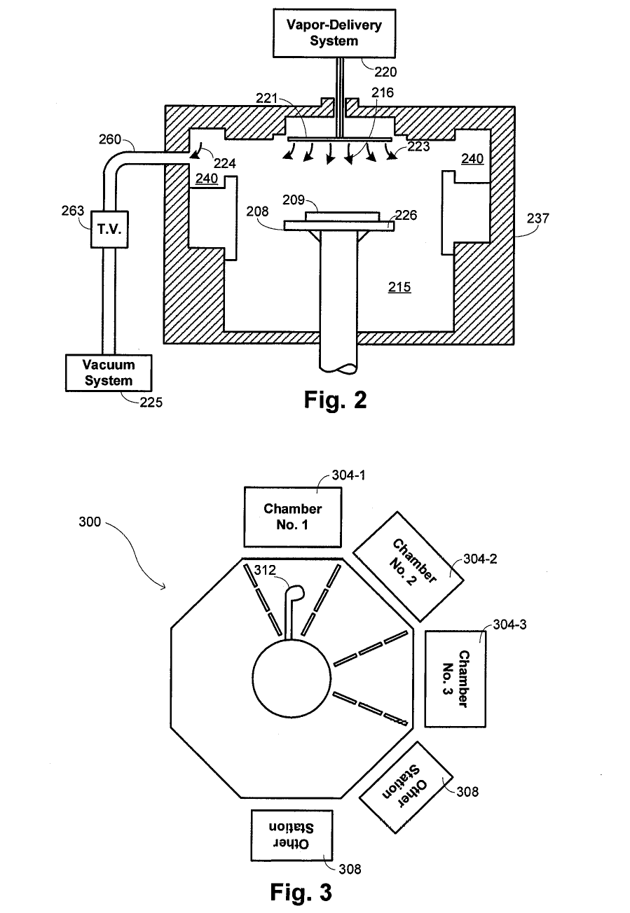

FIG. 2 is a simplified diagram of an exemplary chemical vapor deposition (“CVD”) system, illustrating the basic structure of a chamber in which individual deposition steps can be performed. This system is suitable for performing thermal, sub-atmospheric CVD (“SACVD”) processes, as well as other processes, such as reflow, drive-in, cleaning, etching, deposition, and gettering processes. In some instances multiple-step processes can still be performed within an individual chamber before removal for transfer to another chamber. The major components of the system include, among others, a vacuum chamber 215 that receives process and other gases from a gas or vapor delivery system 220, a vacuum system 225, and a control system (not shown). These and other components are described in more detail below. While the drawing shows the structure of only a single chamber for purposes of illustration, it will be appreciated that multiple chambers with similar structures may be provided as part of a cluster tool, each tailored to perform different aspects of certain overall fabrication processes. However, it is understood that the invention is not so limited, e.g., non-vacuum chambers may be used, and the substrate support structures and methods of the invention may be performed at atmospheric pressures if desired.

The CVD apparatus includes an enclosure assembly 237 that forms vacuum chamber 215 with a gas reaction area 216. A gas distribution structure 221 disperses reactive gases and other gases, such as purge gases, toward one or more substrates 209 held in position by a substrate support structure 208, generally configured as a susceptor. Between gas distribution structure 221 and the substrate 209 is gas reaction area 216. Heaters 226 can be controllably moved between different positions to accommodate different deposition processes as well as for an etch or cleaning process. A center board (not shown) includes sensors for providing information on the position of the substrate.

Different structures may be used for heaters 226. For instance, some embodiments of the invention advantageously use a pair of plates in close proximity and disposed on opposite sides of the substrate support structure 208 to provide separate heating sources for the opposite sides of one or more substrates 209. Merely by way of example, the plates may comprise graphite or SiC in certain specific embodiments. In another instance, the heaters 226 include an electrically resistive heating element (not shown) enclosed in a ceramic. The ceramic protects the heating element from potentially corrosive chamber environments and allows the heater to attain temperatures up to about 1200° C. In an exemplary embodiment, all surfaces of heaters 226 exposed to vacuum chamber 215 are made of a ceramic material, such as aluminum oxide (Al₂O₃ or alumina) or aluminum nitride. In yet other embodiments, radiant lamp heaters (not shown) may preferably be used, positioned in varied locations to rapidly heat the substrate support structure. Such lamp heater arrangements are able to achieve temperatures greater than 1200° C., which may be useful for certain specific applications. Alternatively, a bare metal filament heating element, constructed of a refractory metal such as tungsten, rhenium, iridium, thorium, or their alloys, may be used to heat the substrate.

In certain aspects of the invention, one or more heaters 226 may optionally be incorporated into substrate support structure 208, so as to partially aid in the rapid temperature ramping of the invention. Alternatively, the configuration and/or placement of the one or more heaters 226 in the enclosure assembly 237 may partially aid in the rapid temperature ramping of the invention.

Reactive and carrier gases are supplied from the gas or vapor delivery system 220 through supply lines to the gas distribution structure 221. In some instances, the supply lines may deliver gases into a gas mixing box to mix the gases before delivery to the gas distribution structure. In other instances, the supply lines may deliver gases to the gas distribution structure separately, such as in certain showerhead configurations described below. The gas or vapor delivery system 220 includes a variety of sources and appropriate supply lines to deliver a selected amount of each source to chamber 215 as would be understood by a person of skill in the art. Generally, supply lines for each of the sources include shut-off valves that can be used to automatically or manually shut-off the flow of the gas into its associated line, and mass flow controllers or other types of controllers that measure the flow of gas or liquid through the supply lines. Depending on the process run by the system, some of the sources may actually be liquid or solid sources rather than gases. When liquid sources are used, gas delivery system includes a liquid injection system or other appropriate mechanism (e.g., a bubbler) to vaporize the liquid. Vapor from the liquids is then usually mixed with a carrier gas as would be understood by a person of skill in the art. During deposition processing, gas supplied to the gas distribution structure 221 is vented toward the substrate surface (as indicated by arrows 223), where it may be uniformly distributed radially across the substrate surface in a laminar flow.

Purging gas may be delivered into the vacuum chamber 215 from gas distribution structure 221 and/or from inlet ports or tubes (not shown) through the bottom wall of enclosure assembly 237. Purge gas introduced from the bottom of chamber 215 flows upward from the inlet port past the heater 226 and to an annular pumping channel 240. Vacuum system 225 which includes a vacuum pump (not shown), exhausts the gas (as indicated by arrows 224) through an exhaust line 260. The rate at which exhaust gases and entrained particles are drawn from the annular pumping channel 240 through the exhaust line 260 is controlled by a throttle valve system 263.

The temperature of the walls of deposition chamber 215 and surrounding structures, such as the exhaust passageway, may be further controlled by circulating a heat-exchange liquid through channels (not shown) in the walls of the chamber. The heat-exchange liquid can be used to heat or cool the chamber walls depending on the desired effect. For example, hot liquid may help maintain an even thermal gradient during a thermal deposition process, whereas a cool liquid may be used to remove heat from the system during other processes, or to limit formation of deposition products on the walls of the chamber. Gas distribution manifold 221 also has heat exchanging passages (not shown). Typical heat-exchange fluids water-based ethylene glycol mixtures, oil-based thermal transfer fluids, or similar fluids. This heating, referred to as heating by the “heat exchanger”, beneficially reduces or eliminates condensation of undesirable reactant products and improves the elimination of volatile products of the process gases and other contaminants that might contaminate the process if they were to condense on the walls of cool vacuum passages and migrate back into the processing chamber during periods of no gas flow.

The system controller controls activities and operating parameters of the deposition system. The system controller may include a computer processor and a computer-readable memory coupled to the processor. The processor executes system control software, such as a computer program stored in memory. The processor operates according to system control software (program), which includes computer instructions that dictate the timing, mixture of gases, chamber pressure, chamber temperature, microwave power levels, pedestal position, and other parameters of a particular process. Control of these and other parameters is effected over control lines that communicatively couple the system controller to the heater, throttle valve, and the various valves and mass flow controllers associated with gas delivery system 220.

The physical structure of the cluster tool is illustrated schematically in FIG. 3. In this illustration, the cluster tool 300 includes three processing chambers 304 and two additional stations 308, with robotics 312 adapted to effect transfers of substrates between the chambers 304 and stations 308. The structure permits the transfers to be effected in a defined ambient environment, including under vacuum, in the presence of a selected gas, under defined temperature conditions, and the like. In certain embodiments, optical access may be provided to a transfer chamber in which the transfers are effected through a window 310. A variety of optical elements may be included within or outside the transfer chamber to direct the light as desired.

### 3. SUBSTRATE SUPPORT STRUCTURES WITH RAPID TEMPERATURE CHANGE

Turning now to specific reaction chambers and enclosures in accordance with certain aspects of the present invention, again FIG. 2 illustrates a front perspective view of an exemplary semiconductor enclosure that may be used, e.g., for MOCVD deposition of III-V nitride films like GaN-based LEDs. However, the enclosures and associated components are not limited to such MOCVD processing. In one embodiment, a vacuum chamber 215 generally includes substrate support structure 208, such as a susceptor, configured, and heater(s) 226. Again, the invention is not limited to vacuum chambers, and may include any suitable semiconductor reaction chamber or enclosure. In use, substrate support structure 208 is configured to support one or more substrate wafers 209, and to exhibit rapid temperature change to allow during deposition and processing. In certain embodiments, the substrate support structure 208, may include a susceptor that is configured to support one or more substrate wafers, such as sapphire wafers, and may include one or more support indentations configured to retain such wafers. As understood by those skilled in the art, heater(s) 226, will include controllable heater elements (not shown) to controllably heat a substrate support structure 208 and substrate wafer(s) (209) to desired set-point temperatures. In certain embodiments, the substrate support structure 208, e.g., the susceptor, may incorporate heater elements (not shown). In certain embodiments, the heater elements may be used to aid in temperature uniformity during heating. Any suitable heater element may be incorporated into the substrate support structure, e.g., electrical heater elements may be incorporated into the material of the susceptor, and may controllable heat the susceptor alone or in connection with other heater(s) 226 located in the reactor chamber enclosure.

The substrate support structures 208 of the invention may generally be formed from low thermal mass materials of a nickel-iron alloy, quartz, silicon, silicon carbide, or carbon composite, etc. By way of example, in certain embodiments, the substrate support structures 208 may be about 1-5 mm in thickness, e.g., about 2-4 mm, about 3-5 mm, about 3 mm thick, etc., and exhibit a thermal mass such that substantially uniform temperature heating of the substrate support structure of greater than about 10° C./sec, greater than about 15° C./sec, greater than about 20° C./sec, greater than about 25° C./sec, etc. is achieved. Similar cooling rates may be achieved (e.g., greater than about 10° C./sec, greater than about 15° C./sec, greater than about 20° C./sec, greater than about 25° C./sec, etc.). This ability to change temperature more quickly is a significant advantage when needing to change the temperature of a semiconductor reaction chamber during processing.

In accordance with certain embodiments of the present invention, the substrate support structure is formed from a material having a low thermal mass so as to allow for rapid temperature change (e.g., greater than about 10° C./sec, greater than about 15° C./sec, greater s than about 20° C./sec, greater than about 25° C./sec, etc.). In certain embodiment, the thermal mass may be such that MOCVD reactor heaters having power of, e.g., 30-50 kW, can heat the mass at a rate greater than, e.g., 10° C./sec 20° C./sec, etc., while allowing similar cooling rates. As used herein, thermal mass is a measure of the thermal energy needed to raise a unit mass by one Kelvin. As described herein, in certain embodiments, one or more heaters within the reactor may be radiant lamp heaters, and the substrate support structure may be configured so as to be heated with the desired rapid temperature change by such radiant lamp heaters, alone or in combination with additional heater sources.

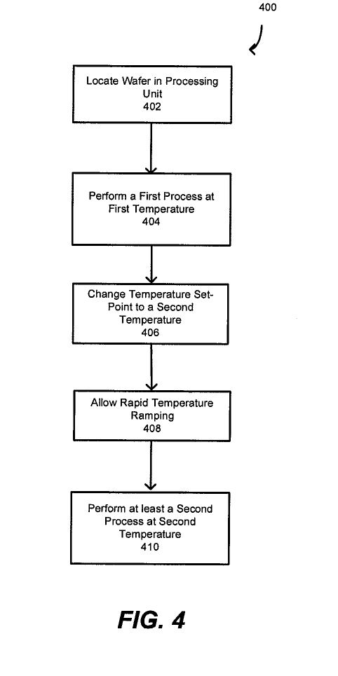

With reference to FIG. 4, yet other embodiments of the invention relate to methods 400 for performing multiple, e.g., III-V nitride film deposition or other related processes in a single semiconductor reaction chamber described herein, wherein at least one of the processes is performed at a temperature which differs from the other processes. Such methods will generally include locating at least a first semiconductor wafer within a semiconductor reaction chamber on a substrate support structure of the invention for a first process 402 and performing a first process in the reaction chamber at a first temperature 404. Following the first process, the set-point temperature of the process is modified to a second temperature 406. The reaction chamber, wafer, and/or substrate support structure (depending on the point of monitoring, as recognized by those skilled in the art) is then allowed to reach its temperature setpoint at a temperature rate of change, e.g., of greater than about 10° C./sec, greater than about 15° C./sec, greater than about 20° C./sec, greater than about 25° C./sec, etc., in accordance with the invention 408. Once the substrate support structure reaches the temperature set point, a second process is located process is performed at the second temperature 410.

Additional process steps may optionally be performed, e.g., at the first temperature prior to changing the set point, at the second temperature, at a third temperature, forth temperature, etc. Further, multiple substrate wafers may be processed at the various steps if desired. For examples, between changes in temperature set points, substrate wafers may be changed.

### EXAMPLES

The following examples are provided to illustrate how the general faceplate and systems described in connection with the present invention may be used rapid temperature equilibration. However, the invention is not limited by the described examples.

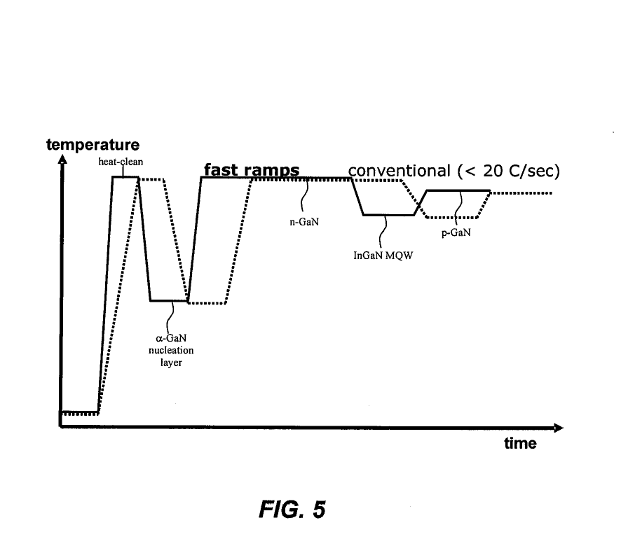

Comparative multiple stage depositions are shown in FIG. 5, wherein the solid line illustrates a representative rapid temperature ramping deposition process with multiple processing steps, while the dotted line represents a conventional (i.e., less than about 5° C./sec) temperature ramping. As shown, the rapid temperature ramping according to the present invention may result in shorter processing times. Further, due in part to the shorter transition periods, less GaN may be allowed to evaporation from the α-GaN nucleation layer.

Having described several embodiments, it will be recognized by those of skill in the art that various modifications, alternative constructions, and equivalents may be used without departing from the spirit of the invention. Additionally, a number of well known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

What is claimed is:

1. A substrate support surface with rapid temperature change capabilities for use in a semiconductor processing unit for deposition of III-V nitride films, the substrate support surface comprising:
a susceptor surface configured so as to allow for rapid temperature change of greater than about 10° C./sec.

2. The substrate support surface of claim 1, wherein susceptor is configured so as allow for rapid temperature change of greater than about 15° C./sec.

3. The substrate support surface of claim 1, wherein susceptor is configured so as allow for rapid temperature change of greater than about 20° C./sec.

4. The substrate support surface of claim 1, wherein the susceptor is comprised of an about 1 mm to about 5 mm thick platform.

5. The substrate support surface of claim 1, wherein the susceptor comprises heater elements to aid in uniform temperature distribution during heating.

6. The substrate support surface of claim 1, wherein the substrate support surface comprises a nickel-iron alloy, quartz, silicon, silicon carbide, or carbon composite.

7. A semiconductor processing unit for use in deposition of III-V nitride films, the semiconductor processing unit comprising:
an enclosure;
a substrate support structure configured to support at least one substrate wafer located within the enclosure;
at least one heater configured to heat the substrate support structure and the at least one substrate wafer during processing; and
a gas delivery system configured to deliver process gases to the enclosure during processing;
wherein the substrate support structure comprises a susceptor surface configured so as to allow for rapid temperature change of greater than about 10° C./sec.

8. The semiconductor processing unit of claim 7, wherein susceptor is configured so as allow for rapid temperature change of greater than about 15° C./sec.

9. The semiconductor processing unit of claim 7, wherein susceptor is configured so as allow for rapid temperature change of greater than about 20° C./sec.

10. The semiconductor processing unit of claim 7, wherein the substrate support structure comprises a nickel-iron alloy, quartz, silicon, silicon carbide, or carbon composite.

11. The semiconductor processing unit of claim 7, wherein at least one heater is a radiant lamp heater.

12. The substrate support surface of claim 7, wherein the susceptor is comprised of an about 1 mm to about 5 mm thick platform.

13. The substrate support surface of claim 7, wherein the susceptor comprises heater elements to aid in uniform temperature distribution during heating.

14. An LED cluster tool comprising a semiconductor processing unit for use in deposition of III-V nitride films, the semiconductor processing unit comprising:
an enclosure;
a substrate support structure configured to support at least one substrate wafer located within the enclosure;
at least one heater configured to heat the substrate support structure and the at least one substrate wafer during processing; and
a gas delivery system configured to deliver process gases to the enclosure during processing;
wherein the substrate support structure comprises a susceptor surface configured so as to allow for rapid temperature change of greater than about 10° C./sec.

15. The LED cluster tool of claim 14, wherein susceptor is configured so as allow for rapid temperature change of greater than about 15° C./sec.

16. The LED cluster tool of claim 14, wherein susceptor is configured so as allow for rapid temperature change of greater than about 20° C./sec.

17. The LED cluster tool of claim 14, wherein the substrate support structure comprises a nickel-iron alloy, quartz, silicon, silicon carbide, or carbon composite.

18. The semiconductor processing unit of claim 14, wherein at least one heater is a radiant lamp heater.

19. The substrate support surface of claim 14, wherein the susceptor is comprised of an about 1 mm to about 5 mm thick platform.

20. The substrate support surface of claim 14, wherein the susceptor comprises heater elements to aid in uniform temperature distribution during heating.

21. A method for performing multiple semiconductor III-V nitride film processes in a single semiconductor processing unit, wherein at least one of the processes is performed at a temperature which differs from the other processes, the method comprising:
providing a semiconductor processing unit for use in deposition of III-V nitride films, the semiconductor processing unit comprising:
an enclosure;
a substrate support structure configured to support at least one substrate wafer located within the enclosure;
at least one heater configured to heat the substrate support structure and the at least one substrate wafer during processing; and
a gas delivery system configured to deliver process gases to the enclosure during processing;
wherein the substrate support structure comprises a susceptor surface configured so as to allow for rapid temperature change of greater than about 10° C./sec.;
locating a first semiconductor wafer within a semiconductor reaction chamber on a substrate support structure;
performing a first process in the reaction chamber at a first temperature at a first temperature;
modifying the set-point temperature of the semiconductor processing unit to a second temperature and allowing the semiconductor substrate support to reach the second temperature at a temperature rate of change of greater than about 10° C./sec; and
performing at least a second process in the reaction chamber at the second temperature.

22. The method of claim 21, wherein susceptor is configured so as allow for rapid temperature change of greater than about 15° C./sec.

23. The method of claim 21, wherein susceptor is configured so as allow for rapid temperature change of greater than about 20° C./sec.

24. The method of claim 21, wherein the temperature change of greater than about 10° C./sec between process steps results in a III-V nitride film with lower film impurities at growth stop interfaces, as compared to III-V nitride films deposited utilizing temperature ramping of less than 10° C./sec between process steps.
